(19) United States
(12) Patent Application Publication
(10) Pub. No.: US 2024/0324177 A1
(43) Pub. Date: Sep. 26, 2024

(54) SEMICONDUCTOR DEVICE

(71) Applicant: Samsung Electronics Co., Ltd., Suwon-si (KR)

(72) Inventors: YONGJIN LEE, Suwon-si (KR); YOUNGGEUN SONG, Suwon-si (KR); MINHEE CHO, Suwon-si (KR)

(21) Appl. No.: 18/604,705

(22) Filed: Mar. 14, 2024

(30) Foreign Application Priority Data
Mar. 24, 2023 (KR) 10-2023-0039260
May 9, 2023 (KR) 10-2023-0059961

(51) Int. Cl. H10B 12/00; H01L 29/786

(52) U.S. Cl. CPC H10B 12/315; H01L 29/78642; H01L 29/7869

(57) ABSTRACT

A semiconductor device includes a substrate, a bit line that extends in a first horizontal direction on the substrate, a first mold layer on the bit line, wherein the first mold layer defines a mold opening that exposes a portion of an upper surface of the bit line and extends in a second horizontal direction that intersects the first horizontal direction, a channel layer on the bit line, one or more word lines on sidewalls of the channel layer and that extend in the second horizontal direction, and a gate insulating layer between the word line and the channel layer, where the channel layer includes a first oxide semiconductor layer, a second oxide semiconductor layer, and an auxiliary channel layer between the first oxide semiconductor layer and the second oxide semiconductor layer.

### CROSS-REFERENCE TO RELATED APPLICATIONS

This application is based on and claims priority under 35 U.S.C. § 119 to Korean Patent Application Nos. 10-2023-0039260, filed on Mar. 24, 2023 and 10-2023-0059961 filed on May 9, 2023 the disclosures of which are incorporated by reference herein in its entirety.

### TECHNICAL FIELD

The present disclosure relates to a semiconductor device, and more particularly, to a semiconductor device including a channel structure.

### BACKGROUND

Due to the development of electronics technology, down-scaling of semiconductor devices (i.e., the reduction in size of the semiconductor devices) is rapidly progressing, and accordingly, a transistor equipped with a channel layer employing an oxide semiconductor material has been proposed to reduce leakage current through the channel area.

### SUMMARY

The present disclosure provides a semiconductor device including a channel layer including a first oxide semiconductor layer, a second oxide semiconductor layer, and a supplementary channel layer arranged between the first oxide semiconductor layer and the second oxide semiconductor layer.

In addition, the present disclosure provides a semiconductor device including the supplementary channel layer having a thickness of less than 1 nm.

In addition, the present disclosure provides a semiconductor device including silicon nitride, and a first mold layer forming an oxygen tunneling structure in which silicon oxide and silicon nitride are sequentially stacked.

According to an aspect of the present disclosure, a semiconductor device includes a substrate; a bit line that extends in a first horizontal direction on the substrate; a first mold layer on the bit line, where the first mold layer defines a mold opening that exposes a portion of an upper surface of the bit line, and where the first mold layer extends in a second horizontal direction that intersects the first horizontal direction; a channel layer on the bit line; one or more word lines that are on sidewalls of the channel layer and that extend in the second horizontal direction; and a gate insulating layer between the one or more word lines and the channel layer, where the channel layer includes a first oxide semiconductor layer, a second oxide semiconductor layer, and an auxiliary channel layer between the first oxide semiconductor layer and the second oxide semiconductor layer.

According to another aspect of the present disclosure, a semiconductor device includes a substrate; a bit line that extends in a first horizontal direction on the substrate; a first mold layer on the bit line, where the first mold layer defines a mold opening that exposes a portion of an upper surface of the bit line; a channel layer on an inner wall of the mold opening, where the channel layer includes a first oxide semiconductor layer on the inner wall of the mold opening or on the bit line, an auxiliary channel layer on the first oxide semiconductor layer, and a second oxide semiconductor layer on the auxiliary channel layer; a word line on sidewalls of the channel layer, where the word line extends in a second horizontal direction that intersects the first horizontal direction; and a gate insulating layer between the word line and the channel layer, where the auxiliary channel layer includes at least one of a two-dimensional (2D) material or indium oxide (In₂O₃).

According to another aspect of the present disclosure, a semiconductor device includes a substrate; a bit line that extends in a first horizontal direction on the substrate; a first mold layer on the bit line, where the first mold layer defines a mold opening that exposes a portion of an upper surface of the bit line, where the first mold layer includes a lower first insulating layer, a second insulating layer on the lower first insulating layer, and an upper first insulating layer on the second insulating layer; a channel layer on an inner wall of the mold opening, where the channel layer includes a first oxide semiconductor layer on the inner wall of the mold opening or on the bit line, an auxiliary channel layer on the first oxide semiconductor layer, and a second oxide semiconductor layer on the auxiliary channel layer; a word line on sidewalls of the channel layer, where the word line extends in a second horizontal direction that intersects the first horizontal direction; a gate insulating layer between the word line and the channel layer; a capacitor structure on the first mold layer; and a contact layer between the channel layer and the capacitor structure, where each of the lower first insulating layer and the upper first insulating layer include silicon nitride, where the second insulating layer includes silicon oxide, and where the auxiliary channel layer includes at least one of a two-dimensional (2D) material or indium oxide (In₂O₃).

### BRIEF DESCRIPTION OF THE DRAWINGS

Embodiments will be more clearly understood from the following detailed description taken in conjunction with the accompanying drawings in which:

FIG. 1 is a layout diagram of a semiconductor device according to an example embodiment of the present disclosure;

FIG. 2 is an enlarged layout diagram of a cell array area in FIG. 1;

FIG. 3 is a cross-sectional view taken along line A1-A1′ in FIG. 2;

FIG. 4 is an enlarged view of a region CX1 in FIG. 3; and

FIGS. 5, 6, 7, 8, 9, 10, 11, 12, 13, and 14 are cross-sectional views illustrating a manufacturing method of a semiconductor device according to embodiments of the present disclosure.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. The term “connected” may be used herein to refer to a physical and/or electrical connection and may refer to a direct or indirect physical and/or electrical connection. The phrase “an element A fills element B” may refer to element A being at least partially within a space defined by element B.

Hereinafter, embodiments of the present disclosure are described in detail with reference to the accompanying drawings. Identical reference numerals are used for the same constituent elements in the drawings, and duplicate descriptions thereof are omitted.

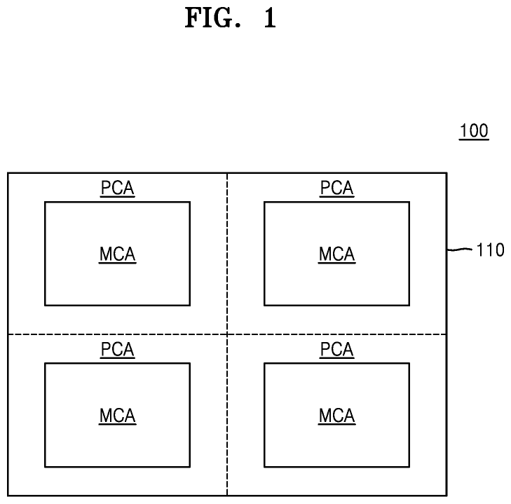

FIG. 1 is a layout diagram of a semiconductor device 100 according to an embodiment of the present disclosure.

Referring to FIG. 1, the semiconductor device 100 may include a substrate 110 including a cell array area MCA and a periphery circuit area PCA. In some embodiments, the cell array area MCA may include a memory cell area of a dynamic random access memory (DRAM) device, and the periphery circuit area PCA may include a core area or a periphery circuit area of the DRAM device. For example, the periphery circuit area PCA may include a periphery circuit transistor (not illustrated) for transmitting signals and/or power to a memory cell array included in the cell array area MCA. In embodiments, the periphery circuit transistor (not illustrated) may constitute various circuits, such as a command decoder, a control logic, an address buffer, a row decoder, a column decoder, a sense amplifier, and a data input/output circuit.

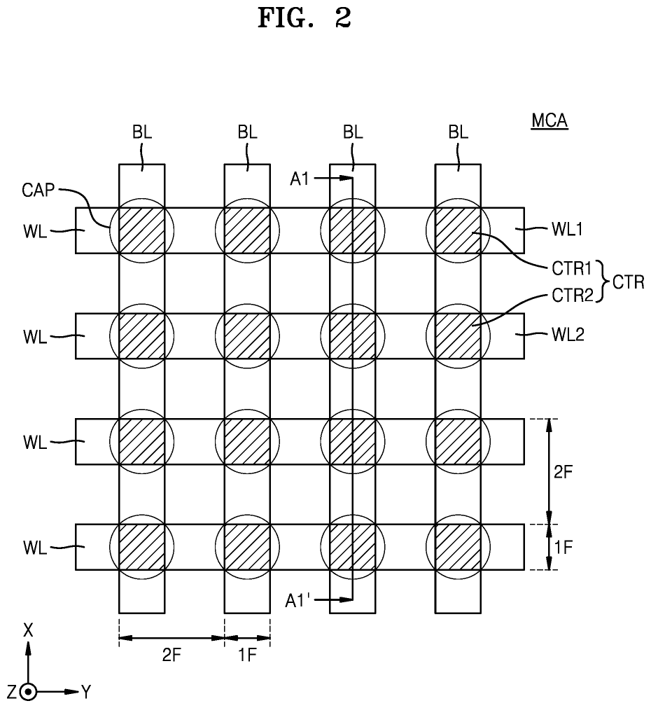

FIG. 2 is an enlarged layout diagram of the cell array area MCA in FIG. 1.

Referring to FIG. 2, a plurality of bit lines BL extending in a first horizontal direction (X direction) and a plurality of word lines WL extending in a second horizontal direction (Y direction) may be arranged on the cell array area MCA of the substrate 110. A plurality of cell transistors CTR may be arranged at intersections of the plurality of word lines WL and the plurality of bit lines BL. A plurality of cell capacitors CAP may be arranged on the plurality of cell transistors CTR, respectively.

The plurality of word lines WL may include a first word line WL1 and a second word line WL2 arranged in the second horizontal direction (Y direction), and the plurality of cell transistors CTR may include a first cell transistor CTR1 and a second cell transistor CTR2 arranged in the second horizontal direction (Y direction). The first cell transistor CTR1 may be arranged on the first word line WL1, and the second cell transistor CTR2 may be arranged on the second word line WL2.

The first cell transistor CTR1 and the second cell transistor CTR2 may have a symmetrical structure with respect to each other. For example, the first cell transistor CTR1 and the second cell transistor CTR2 may have a symmetrical structure with respect to the center line between the first cell transistor CTR1 and the second cell transistor CTR2, which extends in the second horizontal direction (Y direction).

In some embodiments, a width of the plurality of word lines WL and the bit lines BL may be 1F, a pitch (that is, a sum of a width and an interval) of the plurality of word lines WL and the bit lines BL may be 2F, and a unit area for forming one cell transistor CTR may be 4F². Accordingly, because the cell transistor CTR may be a cross point type having a relatively small unit area, the cell transistor CTR may be advantageous for improving the degree of integration of the semiconductor device 100.

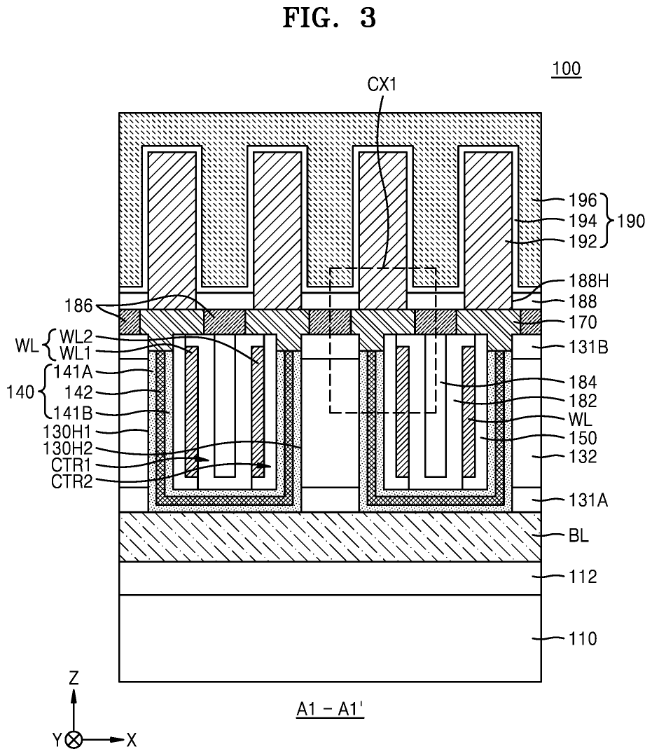

FIG. 3 is a cross-sectional view taken along line A1-A1′ in FIG. 2.

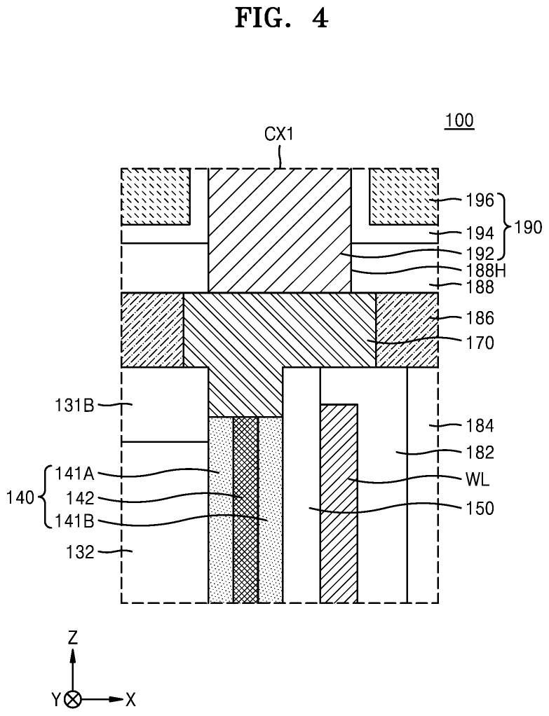

FIG. 4 is an enlarged view of a region CX1 in FIG. 3.

As illustrated in FIG. 3, a lower insulating layer 112 may be arranged on the substrate 110. The substrate 110 may include silicon, for example, monocrystalline silicon, polycrystalline silicon, or amorphous silicon. In some other embodiments, the substrate 110 may include at least one of germanium (Ge), silicon germanium (SiGe), silicon carbon (SiC), gallium arsenide (GaAs), indium arsenide (InAs), and indium phosphate (InP). In some embodiments, the substrate 110 may include a conductive area, for example, a well doped with impurities or a structure doped with impurities. The lower insulating layer 112 may include an oxide layer, a nitride layer, or a combination thereof.

The bit line BL extending in the first horizontal direction (X direction) may be arranged on the lower insulating layer 112. In some embodiments, the bit line BL may include Ti, TiN, Ta, TaN, W, WN, TiSiN, WSiN, polysilicon, or a combination thereof. For example, the bit line BL may also include a conductive layer (not illustrated) and a conductive barrier layer (not illustrated) arranged on upper and lower surfaces of the conductive layer. A bit line insulating layer (not illustrated) extending in the first horizontal direction (X direction) may be arranged on a sidewall of the bit line BL. For example, the bit line insulating layer may be formed to have the same height as the bit line BL while filling a space between two adjacent bit lines BL.

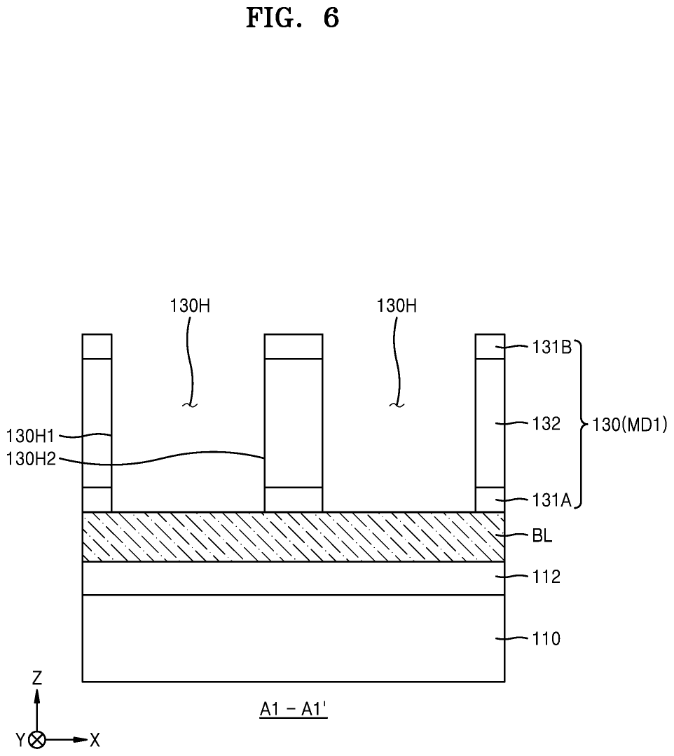

A first mold layer 130 (shown in FIG. 6) may be arranged on the bit line BL and the bit line insulating layer. The first mold layer 130 may include a plurality of mold openings 130H (shown in FIG. 6). The plurality of mold openings 130H may include a first sidewall 130H1 and a second sidewall 130H2 that are opposite to each other. An upper surface of the bit line BL may be exposed to a bottom portion of each of the plurality of mold openings 130H.

The first mold layer 130 may include at least one of silicon oxide, silicon nitride, and silicon oxynitride. According to an embodiment, the first mold layer 130 may be formed as a multilayer structure. For example, the first mold layer 130 may include lower and upper first insulating layers 131A and 131B and a second insulating layer 132. The lower first insulating layer 131A may be arranged on the bit line BL. The second insulating layer 132 may be arranged on the lower first insulating layer 131A. The upper first insulating layer 131B may be arranged on the second insulating layer 132.

In this case, the lower first insulating layer 131A and the upper first insulating layer 131B may include silicon nitride, and the second insulating layer 132 may include silicon oxide. In addition, the thickness in a vertical direction (Z direction) of the second insulating layer 132 may be greater than the thickness in the vertical direction (Z direction) of the lower first insulating layer 131A and the thickness in the vertical direction (Z direction) of the upper first insulating layer 131B, but is not limited thereto.

The first mold layer 130 may be formed as a multilayer structure in which silicon nitride, silicon oxide, and silicon nitride are sequentially stacked. The first mold layer 130 may have a multilayer structure including silicon nitride and silicon oxide, and may form an oxygen tunneling structure.

By forming the first mold layer 130 as a multilayer structure (oxygen tunneling structure) including silicon oxide between silicon nitrides, the channel layer 140 may be passivated. Accordingly, there may be an effect of positively shifting (e.g., increasing) a threshold voltage Vₜₕ without reducing the resistance of the channel layer 140. In addition, by adjusting the annealing temperature, gas, or time of the first mold layer 130, the threshold voltage Vₜₕ may be adjusted in a positive direction (e.g., the threshold voltage Vₜₕ may be increased).

A plurality of channel layers 140 may be arranged on inner walls of the plurality of mold openings 130H. Each of the plurality of channel layers 140 may include a first portion extending from a bottom portion of the plurality of mold openings 130H in the first horizontal direction (X direction), and a second portion connected to the first portion and arranged on the first sidewall 130H1 and the second sidewall 130H2 of the plurality of mold openings 130H. For example, each of the plurality of channel layers 140 may have a nonlinear shaped (e.g., a U-shaped) vertical cross-section.

The second portion of the plurality of channel layers 140 may include a first sidewall and a second sidewall that are opposite to each other. The first sidewall may be in contact with a gate insulating layer 150, and the second sidewall may be in contact with the first mold layer 130. In addition, each of the plurality of channel layers 140 may have an upper surface arranged at a lower level than an upper surface of the first mold layer 130 (e.g., a distance between the upper surface of the first mold layer 130 and the substrate 110 in the vertical direction (Z direction) is greater than a distance between the upper surface of the channel layers 140 and the substrate 110 in the vertical direction (Z direction)).

In some embodiments, each of the plurality of channel layers 140 may include a first oxide semiconductor layer 141A, a second oxide semiconductor layer 141B, and an auxiliary channel layer 142. The channel layer 140 may be formed in a sandwich structure. For example, the auxiliary channel layer 142 may be arranged between the first oxide semiconductor layer 141A and the second oxide semiconductor layer 141B. For example, the first oxide semiconductor layer 141A may contact the upper surface of the bit line BL and the side walls 130H1 and 130H2 of the mold opening 130H. The auxiliary channel layer 142 may be formed on the first oxide semiconductor layer 141A, and the second oxide semiconductor layer 141B may be formed on the auxiliary channel layer 142.

In this embodiment, each of the first oxide semiconductor layer 141A and the second oxide semiconductor layer 141B may include indium gallium zinc oxide (IGZO). The auxiliary channel layer 142 may include a two-dimensional (2D) material or indium oxide (In₂O₃).

In this embodiment, the thickness of the auxiliary channel layer 142 may be less than 1 nm. The thickness of the channel layer 140 may be less than 10 nm. In addition, the thickness of the first oxide semiconductor layer 141A and the thickness of the second oxide semiconductor layer 141B may each be greater than the thickness of the auxiliary channel layer 140.

As the thickness of the auxiliary channel layer 142 decreases, the threshold voltage Vₜₕ of a transistor may increase. According to an embodiment, when the thickness of the auxiliary channel layer 142 including indium oxide In₂O₃ is less than 1 nm, the threshold voltage Vₜₕ of a transistor may exceed 0 V. Accordingly, by forming the auxiliary channel layer 142 between the first oxide semiconductor layer 141A and the second oxide semiconductor layer 141B, the semiconductor device 100 of the present disclosure may have the effect of adjusting the threshold voltage Vₜₕ to exceed 0 V.

In addition, by forming the auxiliary channel layer 142 between the first oxide semiconductor layer 141A and the second oxide semiconductor layer 141B, the semiconductor device 100 may have the effect of improving an on-current (Iₒₙ). By forming the auxiliary channel layer 142 between the first oxide semiconductor layer 141A and the second oxide semiconductor layer 141B, the mobility of electrons may be improved and the on-current (Iₒₙ) may be increased.

The gate insulating layer 150 and the word line WL may be sequentially arranged on the first sidewall of the plurality of channel layers 140. For example, the gate insulating layer 150 may be conformally arranged on an upper surface of the first portion of the plurality of channel layers 140. In addition, the gate insulating layer 150 may be conformally arranged on the first sidewall of the second portion. The word line WL may be arranged on the first sidewall of the second portion of the plurality of channel layers 140. The gate insulating layer 150 may be between the word line WL and the channel layer 140.

The channel layer 140 having a U-shaped vertical cross-section may be arranged in one mold opening 130H. Two word lines WL may be spaced apart from each other on the channel layer 140 in the first horizontal direction (X direction) inside one mold opening 130H. The word line WL may include the first word line WL1 and the second word line WL2 spaced apart from the first word line WL1 in the first horizontal direction (X direction). For example, the first word line WL1 may be arranged to face one second portion of the channel layer 140, and the second word line WL2 may be arranged to face the other second portion of the channel layer 140.

For example, the first word line WL1, one second portion of the channel layer 140, and the gate insulating layer 150 therebetween may constitute the first cell transistor CTR1. The second word line WL2, the other second portion of the channel layer 140, and the gate insulating layer 150 therebetween may constitute the second cell transistor CTR2. Accordingly, the first cell transistor CTR1 and the second cell transistor CTR2 may be arranged to have a symmetrical shape in one mold opening 130H.

In some embodiments, the gate insulating layer 150 may include at least one of a high-k dielectric material and a ferroelectric material, which have a dielectric constant greater than that of silicon oxide. In some embodiments, the gate insulating layer 150 may include at least one of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), and lead scandium tantalum oxide (PbScTaO).

In some embodiments, the word line WL may include Ti, TiN, Ta, TaN, W, WN, TiSiN, WSiN, polysilicon, or a combination thereof.

An insulating liner 182 and a first insulating layer 184 may be arranged between two word lines WL in each of the plurality of mold openings 130H. Each of a plurality of insulating liners 182 may be arranged on one word line WL, and may have an L-shape vertical cross-section. The first insulating layer 184 may be arranged between the plurality of insulating liners 182, and may have a pillar shape cross-section. However, the shapes of the insulating liner 182 and the first insulating layer 184 are not limited thereto, and the shape may vary in other embodiments.

A contact layer 170 may be formed on the channel layer 140. For example, the contact layer 170 may be connected to an upper surface of the channel layer 140. In some embodiments, the lowermost end of the contact layer 170 may be at a lower vertical level than an upper surface of the word line WL (e.g., a distance between the lowermost end of the contact layer 170 and the substrate 110 in the vertical direction (Z direction) is less than a distance between the upper surface of the word line WL and the substrate 110 in the vertical direction (Z direction)). The contact layer 170 may connect the channel layer 140 to a capacitor structure 190. The contact layer 170 may include at least one of a conductive material, for example, a metal, conductive metal nitride, conductive metal carbide, metal silicide, a doped semiconductor material, conductive metal oxynitride, conductive metal oxide, and a 2D material but is not limited thereto.

The second insulating layer 184 may be arranged on both sidewalls of the contact layer 170. Although an upper surface of a second insulating layer 186 is illustrated as at the same level as an upper surface of a plurality of contact layers 170, the embodiment is not limited thereto. For example, the upper surface of the second insulating layer 186 may be at a higher level than the upper surface of the plurality of contact layers 170 (e.g., a distance between the upper surface of the second insulating layer 186 and the substrate 110 in the vertical direction (Z direction) is greater than a distance between the upper surface of the plurality of contact layers 170 and the substrate 110 in the vertical direction (Z direction)).

The insulating liner 182 may include silicon nitride, and the first insulating layer 184 may include silicon oxide. The second insulating layer 184 may include a silicon nitride.

An etching stop layer 188 may be arranged on the contact layer 170 and the second insulating layer 184. The etching stop layer 188 may include an opening 188H, and an upper surface of the contact layer 170 may be exposed at a bottom portion of the opening 188H.

The capacitor structure 190 may be arranged on the etching stop layer 188. The capacitor structure 190 may include a lower electrode 192, a capacitor dielectric layer 194, and an upper electrode 196. The sidewall of the bottom of the lower electrode 192 may be arranged in the opening 188H of the etching stop layer 188, and the lower electrode 192 may extend in the vertical direction (Z direction). The capacitor dielectric layer 194 may be arranged on the sidewall of the lower electrode 192, and the upper electrode 196 may cover or overlap the lower electrode 192 on the capacitor dielectric layer 194.

As the integration of DRAM devices increases, the size of cell transistors may also decrease, and a vertical channel transistor (VCT) including a channel layer including IGZO may have an issue of a reduced on-current (Iₒₙ) when the thickness of the channel layer is equal to or less than 10 nm and an operating voltage is applied.

According to some embodiments, the threshold voltage Vₜₕ may be adjusted by forming the auxiliary channel layer 142 having a thickness of less than 1 nm arranged between the first oxide semiconductor layer 141A and the second oxide semiconductor layer 141B. In addition, by forming the auxiliary channel layer 142, the on-current (Iₒₙ) may be increased.

In addition, by forming the first mold layer 130 in an oxygen tunneling structure with a multilayer structure, the threshold voltage Vₜₕ may be shifted in a positive direction (e.g., the threshold voltage Vₜₕ may increase) without reducing the resistance of the channel layer 140. Accordingly, the semiconductor device 100 may have improved electrical characteristics and improved reliability.

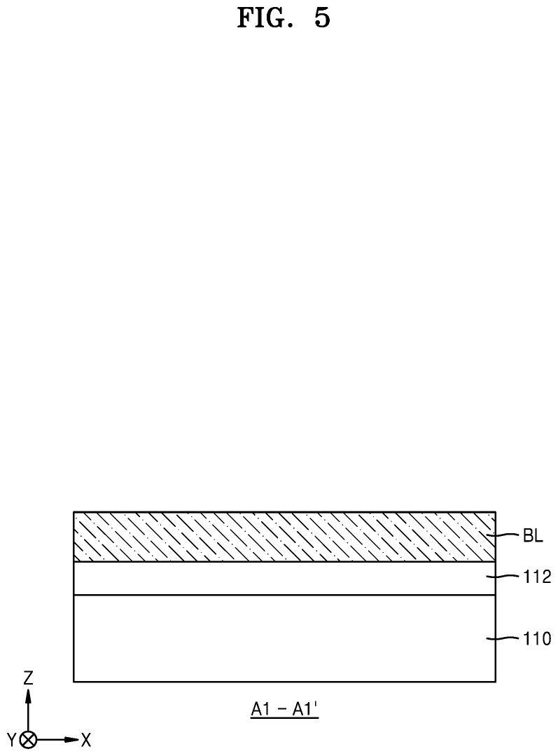

FIGS. 5 through 14 are cross-sectional views illustrating a manufacturing method of the semiconductor device 100 according to embodiments of the present disclosure.

Referring to FIG. 5, a lower insulating layer 112 may be formed on the substrate 110. Next, the plurality of bit lines BL extending in the first horizontal direction (X direction) and a bit line insulating layer (not illustrated) filling spaces between the plurality of bit lines BL may be formed on the lower insulating layer 112. In some embodiments, each of the plurality of bit lines BL may include a conductive barrier layer, a conductive layer, and a conductive barrier layer, which are sequentially arranged on the lower insulating layer 112.

Referring to FIG. 6, the first mold layers 130 (MD1) may be formed on the plurality of bit lines BL and the plurality of bit line insulating layers. In some embodiments, the first mold layer 130 may be formed in a stacked structure. The first mold layer 130 may include at least one of silicon oxide, silicon nitride, and silicon oxynitride, and may be formed to have a relatively large height in the vertical direction (Z direction).

In some embodiments, the first mold layer 130 may include the lower and upper first insulating layers 131A and 131B and the second insulating layer 132. The second insulating layer 132 may be arranged between the lower first insulating layer 131A and the upper first insulating layer 131B. The first insulating layers 131A and 131B may include silicon nitride, and the second insulating layer 132 may include silicon oxide.

The first mold layer 130 may be formed in a multilayer structure in which silicon nitride, silicon oxide, and silicon nitride are sequentially stacked. The first mold layer 130 may have a multilayer structure including silicon nitride and silicon oxide, and may form an oxygen tunneling structure. By forming the first mold layer 130 in a multilayer structure (e.g., an oxygen tunneling structure) including silicon oxide between silicon nitride, as described above, the threshold voltage Vₜₕ may be shifted in the positive direction without reducing the resistance of the channel layer 140.

The plurality of first mold layers 130 may extend in the second horizontal direction (Y direction), and may be formed to be spaced apart from each other at an equal interval in the first horizontal direction (X direction). The mold opening 130H extending in the second horizontal direction (Y direction) may be formed between the plurality of first mold layers 130.

The mold opening 130H may be formed by forming a mask pattern (not illustrated) on the first mold layer 130, and using the mask pattern as an etching mask. The upper surface of the bit line BL may be exposed to the bottom portion of each of the plurality of mold openings 130H. The plurality of mold openings 130H may include the first sidewall 130H1 and the second sidewall 130H2, which are opposite to each other.

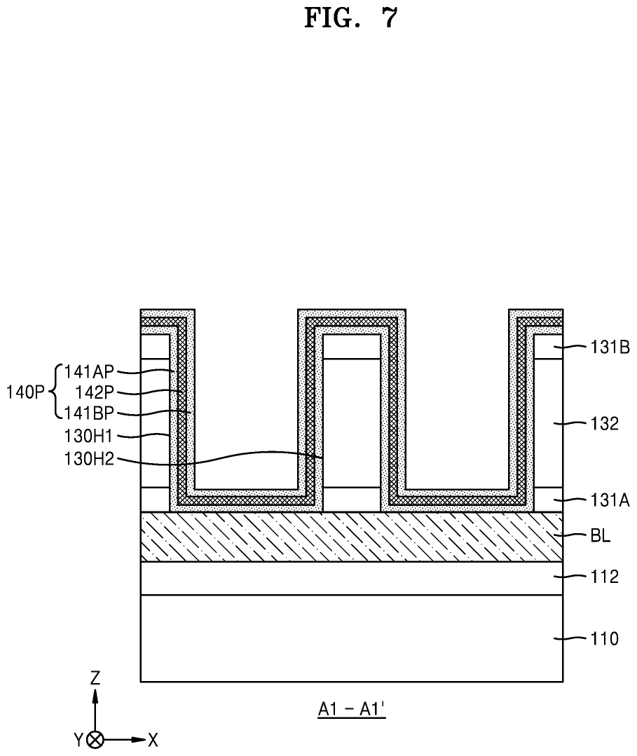

Referring to FIG. 7, a preliminary channel layer 140P may be formed to conformally cover or overlap the inner walls of the mold opening 130H on the first mold layer 130.

In some embodiments, the preliminary channel layer 140P may include a preliminary first oxide semiconductor layer 141AP, a preliminary second oxide semiconductor layer 141BP, and a preliminary auxiliary channel layer 142P. In this case, each of the preliminary first oxide semiconductor layer 141AP and the preliminary second oxide semiconductor layer 141BP may include IGZO. The preliminary auxiliary channel layer 142P may include a 2D material or In₂O₃.

The preliminary channel layer 140P may be formed in a sandwich structure. The preliminary first oxide semiconductor layer 141AP, the preliminary second oxide semiconductor layer 141BP, and the preliminary auxiliary channel layer 142P may be formed by being sequentially stacked on the bit line BL. The preliminary first oxide semiconductor layer 141AP conformally covers or overlaps the inner wall of the mold opening 130H. The preliminary auxiliary channel layer 142P may be conformally formed on the preliminary first oxide semiconductor layer 141AP. The preliminary second oxide semiconductor layer 141BP may be conformally formed on the preliminary auxiliary channel layer 142P.

In some embodiments, the preliminary first oxide semiconductor layer 141AP, the preliminary second oxide semiconductor layer 141BP, and the preliminary auxiliary channel layer 142P may be formed by using at least one of a chemical vapor deposition (CVD) process, a low-pressure CVD process, a plasma reinforced CVD process, a metalorganic CVD (MOCVD) process, and an atomic layer deposition (ALD) process.

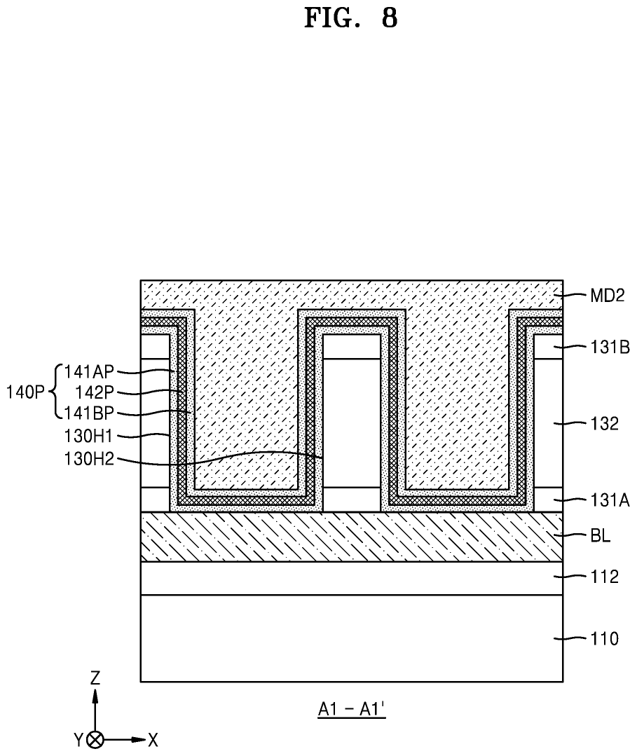

Referring to FIG. 8, a second mold layer MD2 covering or overlapping the preliminary channel layer 140P and filling a portion of the mold opening 130H may be formed. A plurality of second mold layers MD2 may extend in the first horizontal direction (X direction).

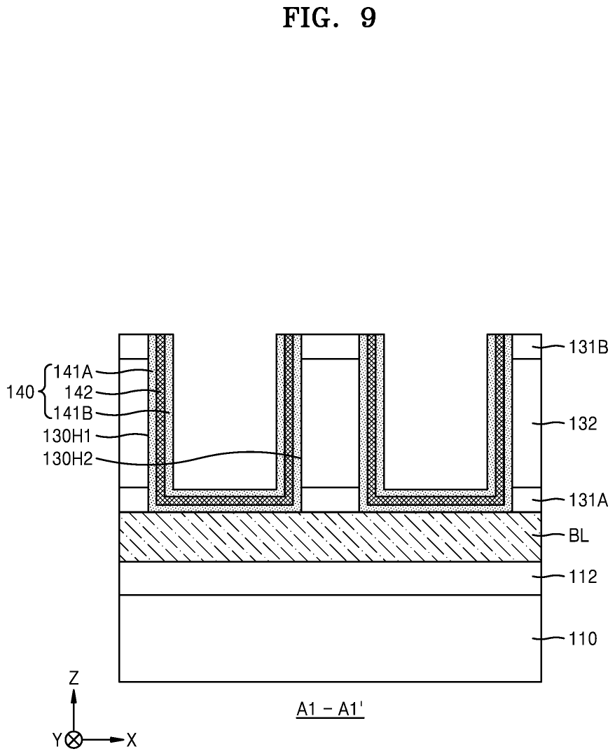

Referring to FIG. 9, the plurality of channel layers 140 may be formed by etchbacking the second mold layer MD2. When the second mold layer MD2 is removed, a portion of the preliminary channel layer 140P may be removed together. A portion of the preliminary channel layer 140P covering or overlapping the upper surface of the first mold layer 130 may be removed to form a plurality of channel layers 140P.

The preliminary channel layer 140P may be removed by using an etchback process or a planarization process to leave the channel layer 140 in the mold opening 130H.

The channel layer 140 having a U-shaped vertical cross-section may be formed inside the mold opening 130H by using the etchback process or the planarization process. In addition, as the preliminary channel layer 140P arranged on the upper surface of the first mold layer 130 is removed, the upper surface of the first mold layer 130 may be exposed. In this case, the upper surface of the channel layer 140 may be arranged at the same level as the upper surface of the first mold layer 130.

Each of the plurality of channel layers 140P may cover or overlap an inner side surface and a bottom surface of the mold opening 130H. Each of the plurality of channel layers 140P may be formed to have a U-shaped vertical cross-section. In this case, the vertical direction (Z direction) level of the channel layer 140P may be the same as the vertical direction (Z direction) level of the first mold layer 130.

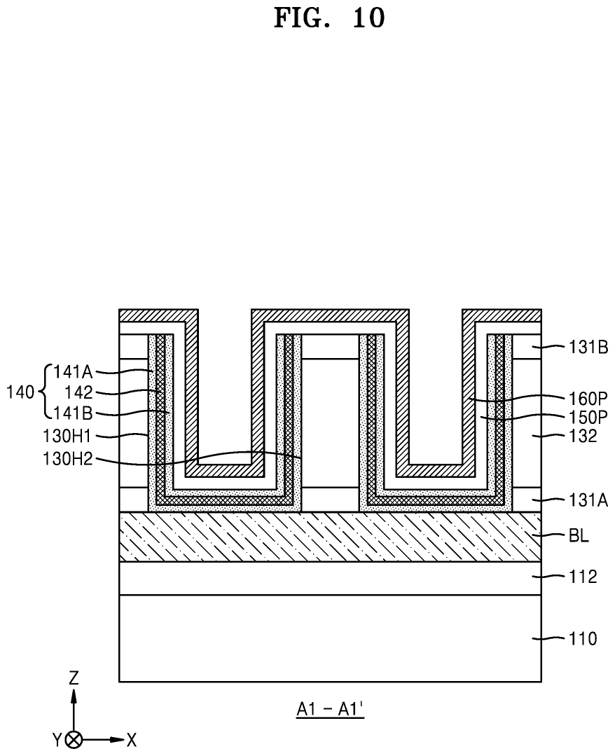

Referring to FIG. 10, a preliminary gate insulating layer 150P and a preliminary gate electrode layer 160P covering or overlapping the channel layer 140 and the first mold layer 130 may be sequentially formed, respectively. The preliminary gate insulating layer 150P may cover or overlap a side surface and an upper surface of the channel layer 140. The preliminary gate insulating layer 150P may cover or overlap an upper surface of the upper first insulating layer 131B. The preliminary gate electrode layer 160P may conformally cover or overlap a side surface and an upper surface of the preliminary gate insulating layer 150P. Each of the preliminary gate insulating layer 150P and the preliminary gate electrode layer 160P may be formed to have a U-shaped vertical cross-section.

In some embodiments, the channel layer 140 may include a first portion extending in the first horizontal direction (X direction) and a second portion connected to both ends of the first portion and extending in the vertical direction (Z direction). The second portion of the channel layer 140 may include a first sidewall and a second sidewall. The first sidewall of the second portion of the channel layer 140 may be surrounded by the preliminary gate insulating layer 150P, and the second sidewall of the second portion thereof may be surrounded by the first mold layer 130.

The preliminary gate insulating layer 150P may include at least one of a high-k dielectric material and a ferroelectric material having a dielectric constant greater than that of silicon oxide. In some embodiments, the preliminary gate insulating layer 150P may include at least one material of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), and lead scandium tantalum oxide (PbScTaO).

In some embodiments, the preliminary gate electrode layer 160P may include Ti, TiN, Ta, TaN, W, WN, TiSiN, WSiN, polysilicon, or a combination thereof.

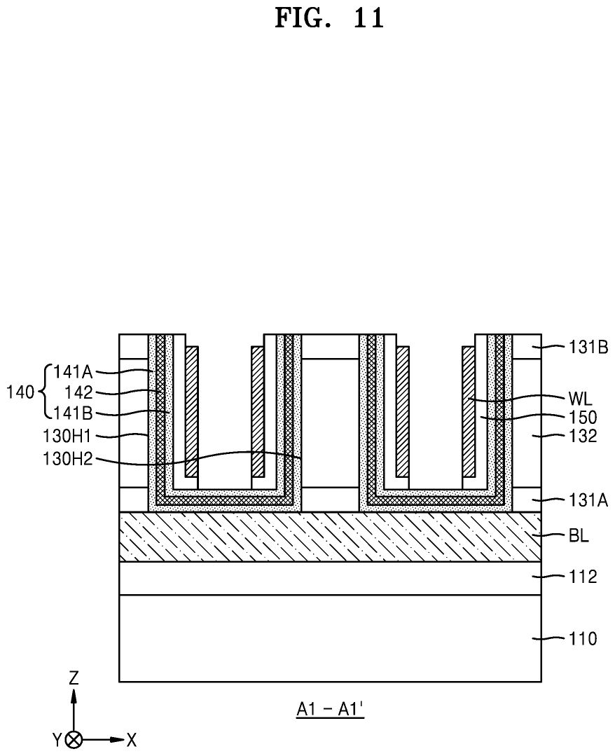

Referring to FIG. 11, portions of the preliminary gate insulating layer 150P and the preliminary gate electrode layer 160P, which cover or overlap at least portions of the upper surface of the plurality of first mold layers 130 and the upper surface of the plurality of channel layers 140, may be removed to form the gate insulating layer 150 and the word line WL, respectively.

Portions of the preliminary gate insulating layer 150P and the preliminary gate electrode layer 160P arranged on the bottom portion of the channel layer 140 may be removed by performing an etching process to expose the upper surface of the channel layer 140. Portions of the preliminary gate insulating layer 150P and the preliminary gate electrode layer 160P may be left on the first sidewall 130H1 and the second sidewall 130H2 of the mold opening 130H. On the other hand, portions of the preliminary gate insulating layer 150P and the preliminary gate electrode layer 160P arranged on the upper surface of the first mold layer 130 may also be removed by the etching process.

The gate insulating layer 150 may be formed to cover or overlap the side surface of the channel layer 140 inside the mold opening 130H and extend in the vertical direction (Z direction). A plurality of gate insulating layers 150 may be arranged on the first sidewall 130H1 and the second sidewall 130H2 of the plurality of mold openings 130H, respectively. The gate insulating layer 150 may cover a portion of the first portion of the channel layer 140 and may have a nonlinear shape (e.g., an L-shape).

The preliminary gate electrode layer 160P may be divided into two word lines WL respectively arranged on the first sidewall 130H1 and the second sidewall 130H2 of the plurality of mold openings 130H. The plurality of word lines WL may be formed to cover or overlap the gate insulating layer 150 inside the mold opening 130H and extend in the vertical direction (Z direction).

In some embodiments, gate electrode layers 160 may be formed to face each other inside one mold opening 130H. A plurality of gate electrode layers 160 may be apart from each other in the first horizontal direction (X direction) and may each extend in the second horizontal direction (Y direction).

In this case, a portion of the upper side of the word line WL in the vertical direction (Z direction) may also be removed by an etching process. Accordingly, the vertical level of the uppermost end of the word line WL may be lower than the vertical level of the uppermost end of the channel layer 140.

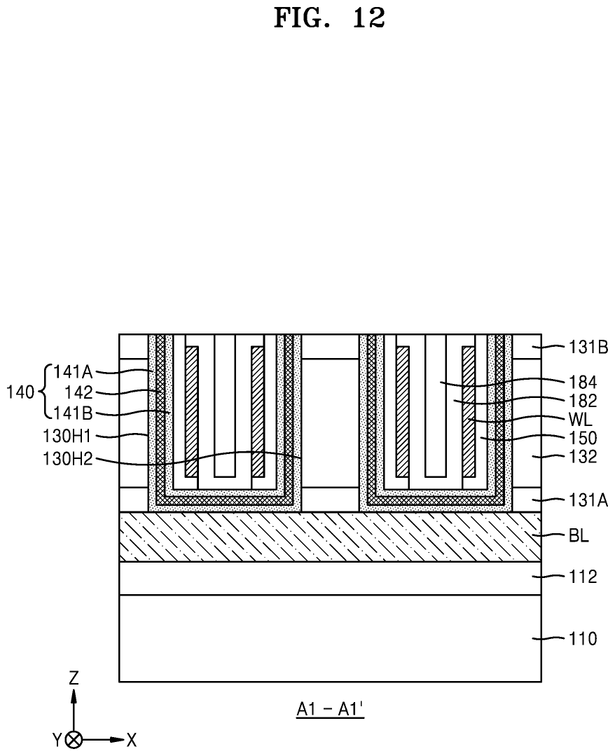

Referring to FIG. 12, the insulating liner 182 and the first insulating layer 184 may be formed inside the mold opening 130H. The insulating liner 182 and the first insulating layer 184 may be arranged between two adjacent word lines WL, and the insulating liner 182 may be arranged on the upper surface of the channel layer 140. The insulating liner 182 and the first insulating layer 184 may be formed by using an etchback process or a planarization process.

In this manner, the first cell transistor CTR1 and the second cell transistor CTR2 may be formed inside the mold opening 130H. The first cell transistor CTR1 and the second cell transistor CTR2 may be spaced apart from each other in the first horizontal direction (X direction), and may be arranged to have a symmetrical shape with respect to each other (refer to FIG. 3).

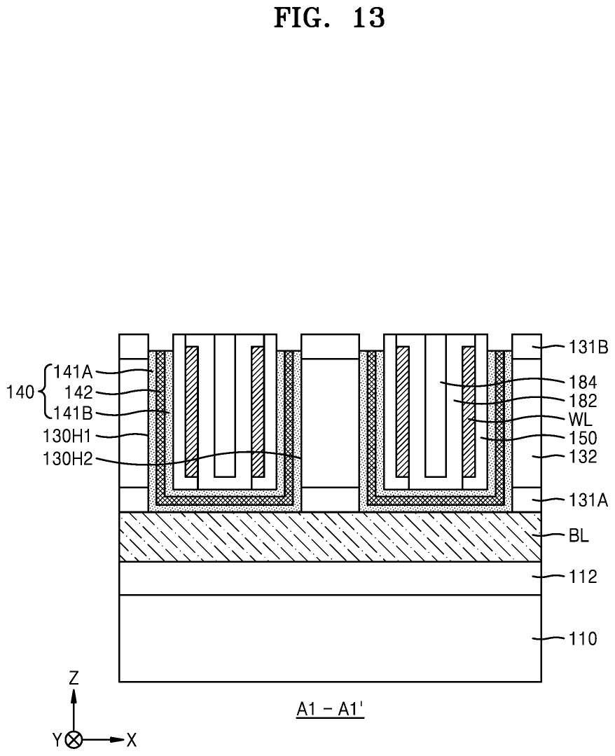

Referring to FIG. 13, a recess process may be performed to remove a portion of an upper side of the channel layer 140. By removing a portion of the upper side of the channel layer 140, the uppermost end of the channel layer 140 may be arranged at a lower level than the uppermost end of the word line WL. In addition, a portion of the sidewall of the upper first insulating layer 131B may be exposed.

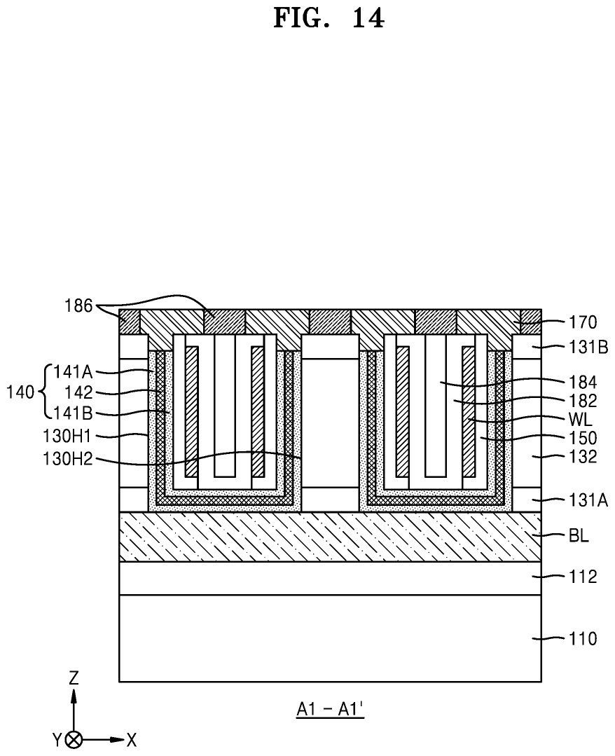

Referring to FIG. 14, the contact layer 170 and the second insulating layer 186 may be formed.

A mask pattern (not illustrated) may be formed on a contact conductive layer (not illustrated), a portion of the contact conductive layer may be removed by using the mask pattern to form the contact layer 170, and the second insulating layer 186 may be formed in an area where the contact conductive layer has been removed. In some embodiments, the contact layer 170 may include Ti, TiN, Ta, TaN, W, WN, TiSiN, WSiN, polysilicon, or a combination thereof.

In some embodiments, the second insulating layer 186 may be formed by using silicon nitride. In addition, the sidewall of the contact layer 170 may be surrounded by the second insulating layer 186, and the bottom surface of the contact layer 170 may cover or overlap a portion of the first mold layer 130, the channel layer 140, the gate insulating layer 150, or the insulating liner 182.

Referring to FIG. 3 again, the etching stop layer 188 may be formed on the contact layer 170 and the second insulating layer 186. The etching stop layer 188 may include the opening 188H, and the upper surface of the contact layer 170 may be exposed on the bottom portion of the opening 188H. Thereafter, the lower electrode 192, the capacitor dielectric layer 194, and the upper electrode 196 may be sequentially formed on the etching stop layer 188.

A plurality of lower electrodes 192 may be formed to extend in the vertical direction (Z direction) from the upper surface of the contact layer 170 exposed on the bottom surface of the opening 188H of the etching stop layer 188. Thereafter, the capacitor dielectric layer 194 and the upper electrode 196 may be respectively and sequentially formed on the plurality of lower electrodes 192 to form the semiconductor device 100 including a plurality of capacitor structures 190.

In this case, the lower electrode 192 may have a pillar shape extending in the vertical direction (Z direction) from the upper surface of the contact layer 170 but is not limited thereto, and the lower electrode 192 may be formed to have a cylindrical shape extending in the vertical direction (Z direction) from the upper surface of the contact layer 170. The capacitor dielectric layer 194 may be formed to conformally extend along the profile of the side surfaces and upper surfaces of the plurality of lower electrodes 192, and along an upper surface of the etching stop layer 188. The upper electrode 196 may be formed to cover or overlap the capacitor dielectric layer 194.

While the present disclosure has been particularly shown and described with reference to embodiments thereof, it will be understood that various changes in form and details may be made therein without departing from the spirit and scope of the following claims.

What is claimed is:

1. A semiconductor device comprising:
a substrate;
a bit line that extends in a first horizontal direction on the substrate;
a first mold layer on the bit line, wherein the first mold layer defines a mold opening that exposes a portion of an upper surface of the bit line, and wherein the first mold layer extends in a second horizontal direction that intersects the first horizontal direction;
a channel layer on the bit line;
one or more word lines that are on sidewalls of the channel layer and that extend in the second horizontal direction; and
a gate insulating layer between the one or more word lines and the channel layer,
wherein the channel layer comprises a first oxide semiconductor layer, a second oxide semiconductor layer, and an auxiliary channel layer between the first oxide semiconductor layer and the second oxide semiconductor layer.

2. The semiconductor device of claim 1, wherein each of the first oxide semiconductor layer and the second oxide semiconductor layer comprises indium gallium zinc oxide (IGZO).

3. The semiconductor device of claim 1, wherein the auxiliary channel layer comprises at least one of a two-dimensional (2D) material and indium oxide (In₂O₃).

4. The semiconductor device of claim 1, wherein a thickness of the auxiliary channel layer is less than 1 nm.

5. The semiconductor device of claim 1, wherein the first mold layer comprises a lower first insulating layer on the bit line, a second insulating layer on the lower first insulating layer, and an upper first insulating layer on the second insulating layer.

6. The semiconductor device of claim 5, wherein the lower first insulating layer and the upper first insulating layer comprise silicon nitride, and the second insulating layer comprises silicon oxide.

7. The semiconductor device of claim 5, wherein, in a vertical direction, a thickness of the second insulating layer is greater than a thickness of the lower first insulating layer and a thickness of the upper first insulating layer.

8. The semiconductor device of claim 1, wherein a thickness of the first oxide semiconductor layer and a thickness of the second oxide semiconductor layer are greater than a thickness of the auxiliary channel layer.

9. The semiconductor device of claim 1, wherein the channel layer is on an inner wall of the mold opening or on the upper surface of the bit line.

10. The semiconductor device of claim 1, wherein the channel layer extends on first and second inner walls of the mold opening and on the upper surface of the bit line between the opposing first and second inner sidewalls.

11. The semiconductor device of claim 1, wherein the one or more word lines comprise a first word line and a second word line spaced apart from each other in the first horizontal direction in the mold opening, and
wherein the semiconductor device further comprises an insulating liner and a first insulating layer between the first word line and the second word line.

12. A semiconductor device comprising:
a substrate;
a bit line that extends in a first horizontal direction on the substrate;
a first mold layer on the bit line, wherein the first mold layer defines a mold opening that exposes a portion of an upper surface of the bit line;
a channel layer on an inner wall of the mold opening, wherein the channel layer comprises a first oxide semiconductor layer on the inner wall of the mold opening or on the bit line, an auxiliary channel layer on the first oxide semiconductor layer, and a second oxide semiconductor layer on the auxiliary channel layer;
a word line on sidewalls of the channel layer, wherein the word line extends in a second horizontal direction that intersects the first horizontal direction; and
a gate insulating layer between the word line and the channel layer,
wherein the auxiliary channel layer comprises at least one of a two-dimensional (2D) material and indium oxide (In₂O₃).

13. The semiconductor device of claim 12, wherein each of the first oxide semiconductor layer and the second oxide semiconductor layer comprises indium gallium zinc oxide (IGZO).

14. The semiconductor device of claim 12, wherein a thickness of the auxiliary channel layer is less than 1 nm.

15. The semiconductor device of claim 12, wherein the first mold layer comprises:
a lower first insulating layer on the bit line and comprising silicon nitride;
a second insulating layer on the lower first insulating layer and comprising silicon oxide; and
an upper first insulating layer on the second insulating layer and comprising silicon nitride.

16. The semiconductor device of claim 15, wherein, in a vertical direction, a thickness of the second insulating layer is greater than a thickness of the lower first insulating layer and a thickness of the upper first insulating layer.

17. The semiconductor device of claim 12, wherein a thickness of the first oxide semiconductor layer and a thickness of the second oxide semiconductor layer are greater than a thickness of the auxiliary channel layer.

18. A semiconductor device comprising:
a substrate;
a bit line that extends in a first horizontal direction on the substrate;
a first mold layer on the bit line, wherein the first mold layer defines a mold opening that exposes a portion of an upper surface of the bit line, wherein the first mold layer comprises a lower first insulating layer, a second insulating layer on the lower first insulating layer, and an upper first insulating layer on the second insulating layer;
a channel layer on an inner wall of the mold opening, wherein the channel layer comprises a first oxide semiconductor layer on the inner wall of the mold opening or on the bit line, an auxiliary channel layer on the first oxide semiconductor layer, and a second oxide semiconductor layer on the auxiliary channel layer;
a word line on sidewalls of the channel layer, wherein the word line extends in a second horizontal direction that intersects the first horizontal direction;
a gate insulating layer between the word line and the channel layer;
a capacitor structure on the first mold layer; and
a contact layer between the channel layer and the capacitor structure,
wherein each of the lower first insulating layer and the upper first insulating layer comprise silicon nitride,
wherein the second insulating layer comprises silicon oxide, and
wherein the auxiliary channel layer comprises at least one of a two-dimensional (2D) material and indium oxide (In₂O₃).

19. The semiconductor device of claim 18, wherein each of the first oxide semiconductor layer and the second oxide semiconductor layer comprises indium gallium zinc oxide (IGZO).

20. The semiconductor device of claim 18, wherein a thickness of the auxiliary channel layer is less than 1 nm.
